(19) United States
(12) Patent Application Publication
(10) Pub. No.: US 2009/0209096 A1
(43) Pub. Date: Aug. 20, 2009

(54) METHOD FOR MANUFACTURING SEMICONDUCTOR DEVICE HAVING DECREASED CONTACT RESISTANCE

(76) Inventors: Nam Yeal LEE, Daejeonsi (KR); Seung Jin YEOM, Gyeonggi-do (KR); Baek Mann KIM, Gyeonggi-do (KR); Dong Ha JUNG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/345,833

(22) Filed: Dec. 30, 2008

(30) Foreign Application Priority Data
Feb. 14, 2008 (KR) 10-2008-0013285

(51) Int. Cl. H01L 21/4763; H01L 21/441

(52) U.S. Cl. 438/586; 438/664; 257/E21.477; 257/E21.495

(57) ABSTRACT

A method for manufacturing a semiconductor device includes the steps of forming an insulation layer having a contact hole, on a semiconductor substrate, forming a Co layer on the insulation layer including a surface of the contact hole, conducting primary annealing to allow the Co layer and a portion of the semiconductor substrate to react with each other such that a CoSi layer is formed at an interface therebetween. The resultant semiconductor substrate is cleaned to remove a portion of the Co layer not having reacted in the primary annealing. A barrier layer is formed on the insulation layer, the CoSi layer, and the surface of the contact hole. A secondary annealing is conducted to convert the CoSi layer into a CoSi₂ layer.

### CROSS-REFERENCE TO RELATED APPLICATIONS

The present application claims priority to Korean patent application number 10-2008-0013285 filed on Feb. 14, 2008, which is incorporated herein by reference in its entirety.

### BACKGROUND OF THE INVENTION

The present invention relates generally to a method for manufacturing a semiconductor device, and more particularly to a method for manufacturing a semiconductor device capable of decreasing contact resistance.

In a semiconductor device, contact plugs are formed on a semiconductor substrate on both sides of a gate so as to electrically connect the junction regions of transistors (i.e., source and drain regions) with a bit line and a capacitor.

As semiconductor devices follow the current design trend of miniaturization, the integration level of the semiconductor device continues to increase, which results in an increase of the contact resistance of the contact plugs. In order to decrease the contact resistance, a method of forming a metal silicide layer, for example, a CoSi₂ layer, has been proposed. The CoSi₂ layer provides advantages in that it has low specific resistance and is stable in a high temperature annealing process. Further, because the CoSi₂ layer has low impurity dependency, it is possible to maintain a constant contact resistance between the CoSi₂ layer and a junction region, which is ion-implanted with N-type or P-type impurities.

Hereafter, a conventional method for forming a contact plug will be briefly described.

An insulation layer is formed on a semiconductor substrate, and a contact hole is defined by etching the insulation layer to expose a portion of the semiconductor substrate. A Co layer is formed on the insulation layer and the surface of the contact hole. A primary annealing is conducted such that the Co layer reacts with the portion of the semiconductor substrate which is placed thereunder and a CoSi layer is formed at the interface therebetween. A cleaning process is conducted such that the portion of the Co layer having not reacted in the primary annealing is removed. Then, a secondary annealing is conducted such that the CoSi layer reacts with the portion of the semiconductor substrate placed thereunder and is converted into a CoSi₂ layer. A conductive layer is filled in the contact hole having the CoSi₂ layer formed therein, and through this, a contact plug is formed.

In the conventional method for forming a contact plug as described above, an amorphous Si-rich layer is likely to be formed on the CoSi layer while conducting the cleaning process. The amorphous Si-rich layer can remain on the CoSi₂ layer even after the secondary annealing is conducted, thereby increasing the contact resistance of the contact plug.

FIGS. 1A and 1B are graphs showing the resistance of an NMOS device and a PMOS device when a contact plug is formed according to the conventional art.

Referring to FIGS. 1A and 1B, in the event that the CoSi₂ layer is formed on the bottom of the contact hole according to the conventional art, since the Si-rich layer is formed on the CoSi₂ layer, contact resistance increases when compared to the case of forming a TiSi₂ layer on the bottom of the contact hole.

### SUMMARY OF THE INVENTION

Embodiments of the present invention include a method for manufacturing a semiconductor device, which can decrease contact resistance.

In one embodiment of the present invention, a method for manufacturing a semiconductor device comprises the steps of forming an insulation layer having a contact hole, on a semiconductor substrate; forming a Co layer on the insulation layer including a surface of the contact hole; conducting primary annealing to allow the Co layer and a portion of the semiconductor substrate to react with each other such that a CoSi layer is formed at an interface therebetween; cleaning the resultant semiconductor substrate such that a portion of the Co layer not having reacted in the primary annealing is removed; forming a barrier layer on the insulation layer including the CoSi layer and the surface of the contact hole; and conducting secondary annealing to allow the CoSi layer to be converted into a CoSi₂ layer.

After the step of forming the insulation layer and before the step of forming the Co layer, the method further comprises the step of removing a native oxide layer produced on a surface of the insulation layer having the contact hole.

After the step of forming the Co layer and before the step of conducting primary annealing, the method further comprises the step of forming a capping layer on the Co layer.

The capping layer comprises a Ti layer or a TiN layer.

The step of forming the Co layer and the step of forming the capping layer are implemented in situ.

The primary annealing is conducted through RTA.

The primary annealing is conducted at a temperature of 400˜550° C.

Cleaning is conducted using an SPM solution.

The barrier layer comprises a stack structure of a Ti layer and a TiN layer.

The secondary annealing is conducted through RTA.

The secondary annealing is conducted at a temperature of 700˜800° C.

After the step of conducting the secondary annealing, the method further comprises the steps of forming a glue layer on the barrier layer; and forming a conductive layer on the glue layer to fill the contact hole.

The glue layer comprises a TiN layer.

The conductive layer comprises a W layer.

In another embodiment of the present invention, a method for manufacturing a semiconductor device comprises the steps of forming a gate on a semiconductor substrate; forming a junction region in a surface of the semiconductor substrate on each of both sides of the gate; forming an insulation layer having a contact hole exposing the junction region, on the semiconductor substrate formed with the junction region; forming a Co layer on the insulation layer including a surface of the contact hole; conducting primary annealing to allow the Co layer and a portion of the semiconductor substrate to react with each other such that a CoSi layer is formed at an interface therebetween; cleaning the resultant semiconductor substrate such that a portion of the Co layer not having reacted in the primary annealing is removed; forming a barrier layer on the insulation layer including the CoSi layer and the surface of the contact hole; and conducting secondary annealing to allow the CoSi layer to be converted into a CoSi₂ layer.

After the step of forming the insulation layer and before the step of forming the Co layer, the method further comprises the step of removing a native oxide layer produced on a surface of the junction region which constitutes a bottom of the contact hole.

After the step of forming the Co layer and before the step of conducting primary annealing, the method further comprises the step of forming a capping layer on the Co layer.

The capping layer comprises a Ti layer or a TiN layer.

The step of forming the Co layer and the step of forming the capping layer are implemented in situ.

The primary annealing is conducted through RTA.

The primary annealing is conducted at a temperature of 400˜550° C.

Cleaning is conducted using an SPM solution.

The barrier layer comprises a stack structure of a Ti layer and a TiN layer.

The secondary annealing is conducted through RTA. The secondary annealing is conducted at a temperature of 700˜800° C.

After the step of conducting the secondary annealing, the method further comprises the steps of forming a glue layer on the barrier layer; and forming a conductive layer on the glue layer to fill the contact hole.

The glue layer comprises a TiN layer.

The conductive layer comprises a W layer.

### BRIEF DESCRIPTION OF THE DRAWINGS

FIGS. 1A and 1B are graphs showing resistance of an NMOS device and a PMOS device when a contact plug is formed according to a conventional art.

FIGS. 2A through 2G are cross-sectional views showing the processes of a method for manufacturing a semiconductor device in accordance with an embodiment of the present invention.

FIGS. 3A and 3B are graphs showing resistance of an NMOS device and a PMOS device when a contact plug is formed in accordance with the embodiment of the present invention.

FIGS. 4A and 4B are graphs showing leakage current of an NMOS device and a PMOS device when a contact plug is formed in accordance with the embodiment of the present invention.

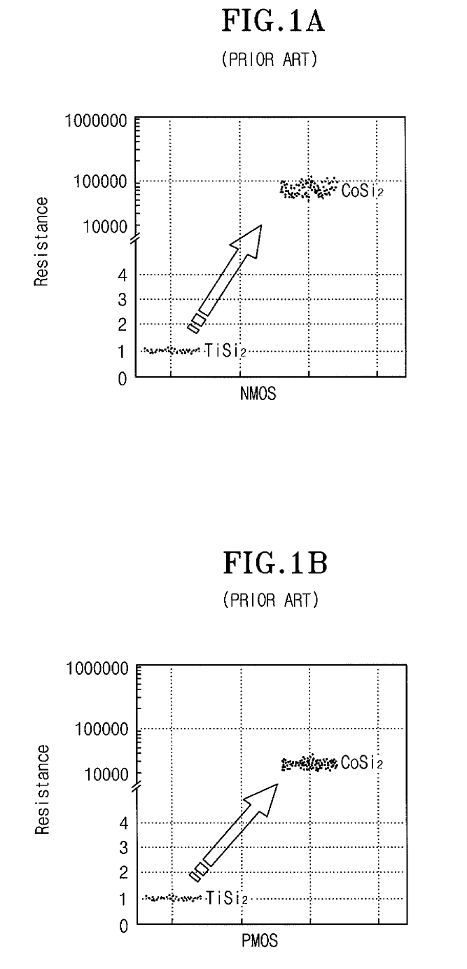

### DESCRIPTION OF SPECIFIC EMBODIMENT

Hereafter, specific embodiments of the present invention will be described in detail with reference to the accompanying drawings.

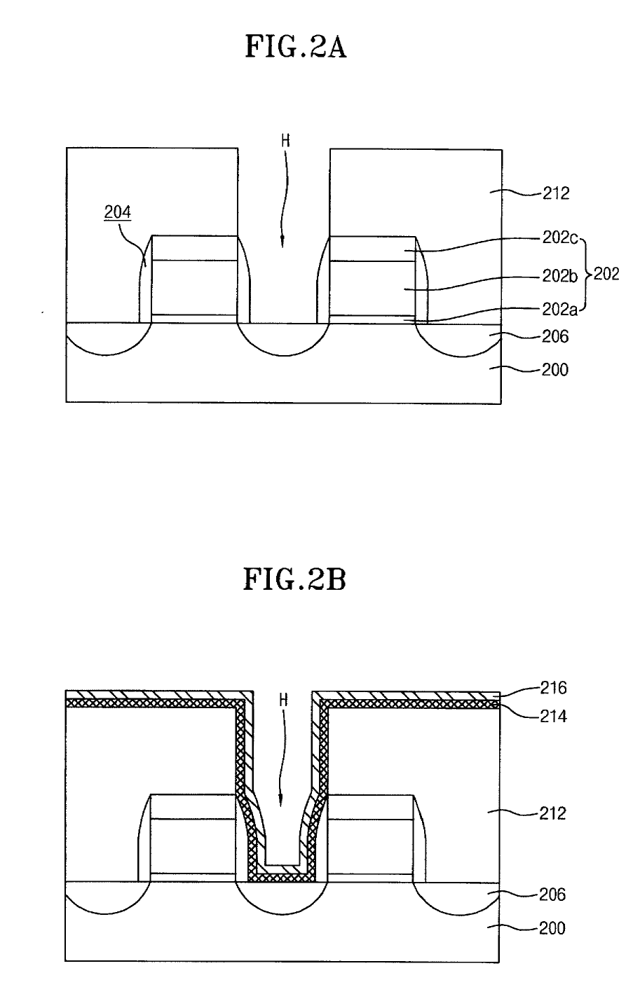

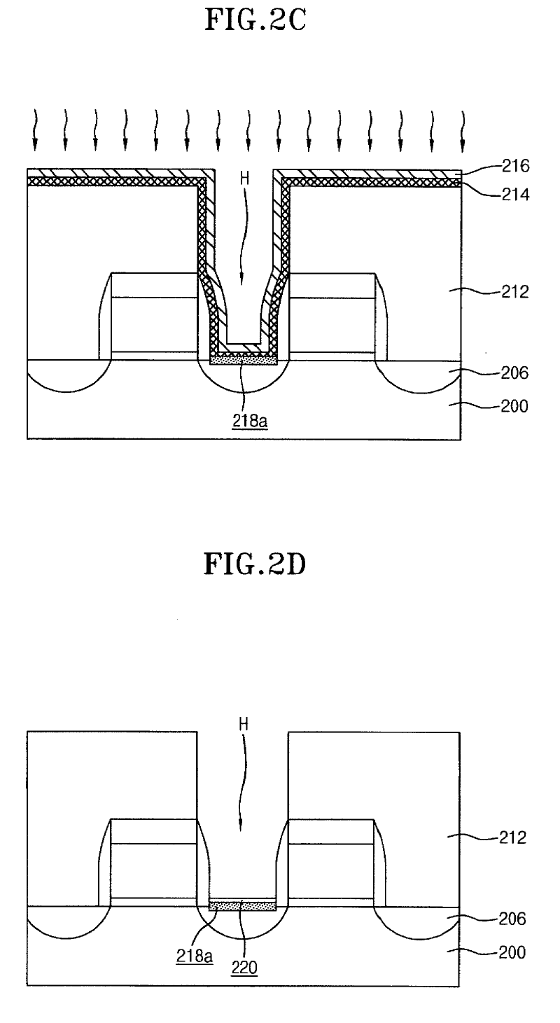

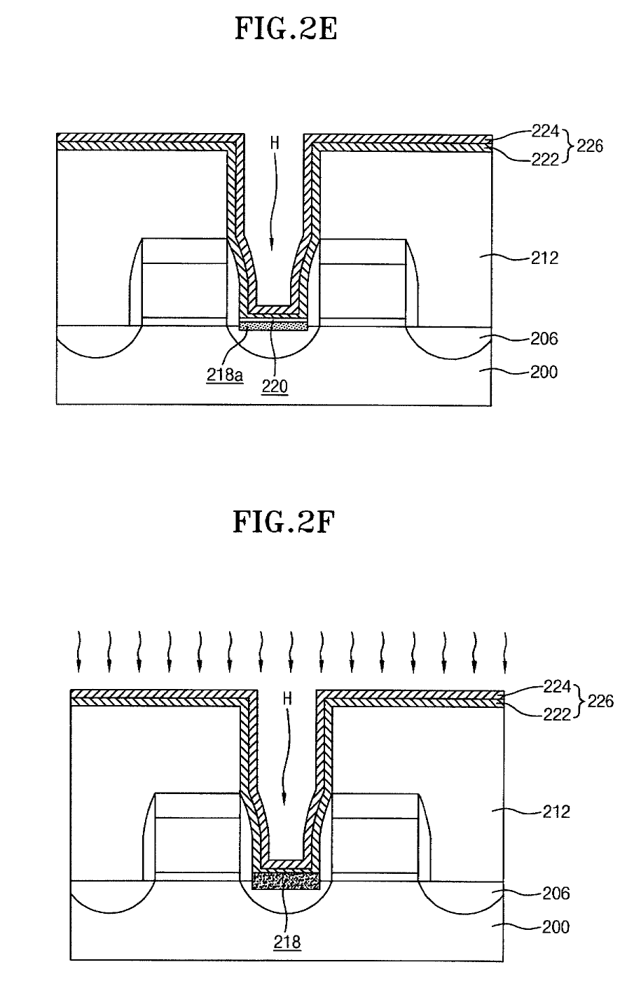

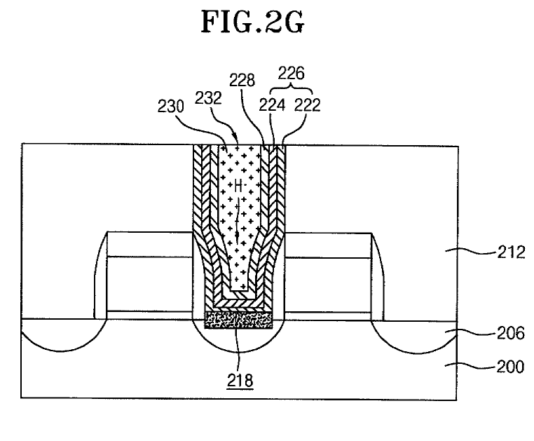

FIGS. 2A through 2G are cross-sectional views showing the processes of a method for manufacturing a semiconductor device in accordance with an embodiment of the present invention.

Referring to FIG. 2A, a gate insulation layer 202a, a gate conductive layer 202b, and a gate hard mask layer 202c are sequentially formed on a semiconductor substrate 200. Then the gate insulation layer 202a, the gate conductive layer 202b, and the gate hard mask layer 202c are etched to form gates 202. Gate spacers 204 are formed on both sidewalls of the gates 202. Junction regions 206 are formed in the semiconductor substrate 200 on both sides of the gates 202. An insulation layer 212 is formed on the semiconductor substrate 200 to cover the gates 202, then a contact hole H is defined to expose a portion of the semiconductor substrate 200 by etching the insulation layer 212. Preferably, the contact hole H is defined such that each of the junction regions 206 formed in the semiconductor substrate 200 on both sides of the gates 202, specifically, the junction region 206 for a bit line contact is exposed.

Referring to FIG. 2B, a native oxide layer, which is produced on the portion of the semiconductor substrate 200 constituting the bottom of the contact hole H, that is, the surface of the junction region 206, is removed. The removal of the native oxide layer is implemented in a wet type using a wet chemical or a dry type. A Co layer 214 is formed on the insulation layer 212 and the surface of the contact hole H, from which the native oxide layer has been removed. The Co layer 214 is formed through chemical vapor deposition (CVD), physical vapor deposition (PVD) or atomic layer deposition (ALD). A capping layer 216 is formed on the Co layer 214 to prevent both the oxidation and the diffusion of the Co layer 214. The capping layer 216 is formed as a Ti layer or a TiN layer. The Co layer 214 and the capping layer 216 are formed in situ under a vacuum state.

Referring to FIG. 2C, a primary annealing is conducted on the resultant semiconductor substrate 200 formed with the capping layer 216 and the Co layer 214 such that the Co layer 214 and the portion of the semiconductor substrate 200 placed thereunder, that is, the junction region 206, react with each other. Through this, a CoSi layer 218a is formed at the interface of the Co layer 214 and the semiconductor substrate 200, that is, at the interface of the Co layer 214 and the junction region 206. The primary annealing is conducted through rapid thermal annealing (RTA), for example, at a temperature in the range of 400˜550° C.

Referring to FIG. 2D, a cleaning process is conducted on the resultant semiconductor substrate 200 formed with the CoSi layer 218a to remove the capping layer 216 and the portion of the Co layer 214 that did not react in the primary annealing. The cleaning process is conducted using an sulfuric acid peroxide mixture (SPM) solution containing a sulfuric acid solution and a peroxide solution. During the cleaning process, an amorphous abnormal layer, for example, an amorphous Si-rich layer 220 is formed on the CoSi layer 218a.

Referring to FIG. 2E, a barrier layer 226 is formed on the insulation layer 212, the amorphous Si-rich layer 220, and the surface of the contact hole H. The barrier layer 226 has a stacked structure of a Ti layer 222 and a TiN layer 224. The TiN layer 224 is formed in situ with respect to the Ti layer 222 so as to prevent the oxidation of the Ti layer 222.

Referring to FIG. 2F, a secondary annealing is conducted on the resultant semiconductor substrate 200 formed with the barrier layer 226 such that the CoSi layer 218a and the portion of the semiconductor substrate 200 placed thereunder, that is, the junction region 206, react with each other. Through this, the CoSi layer 218a is converted into a CoSi₂ layer 218. The secondary annealing is conducted through RTA, for example, at a temperature in the range of 700˜800° C.

In the present invention, while the secondary annealing is conducted, the CoSi layer 218a reacts with both the portion of the semiconductor substrate 200 placed thereunder and the amorphous Si-rich layer 220 to be converted into the CoSi₂ layer 218. Accordingly, in the present invention, the CoSi₂ layer 218 is formed through the secondary annealing, and the amorphous Si-rich layer 220 can be removed through the secondary annealing.

Referring to FIG. 2G, a glue layer 228 is formed on the barrier layer 226, subsequently a conductive layer for a plug, for example, a W layer 230, is formed on the glue layer 228 to completely fill the contact hole H. Subsequently, by removing the portions of the W layer 230, the glue layer 228, and the barrier layer 226 formed on the insulation layer 212, a contact plug 232 is formed in the contact hole H.

The glue layer 228 functions to prevent a WF₆ gas serving as a source gas from leaking to the CoSi₂ layer 218 and to the portion of the semiconductor substrate 200 placed thereunder while subsequently forming the W layer 230 and the glue layer 228 also functions to increase the adhesion force of the W layer 230. The glue layer 228 comprises, for example, a TiN layer and is formed through sputtering or CVD. In the present invention, the glue layer 228 is formed to a thickness that is less than that of the conventional art, and therefore, the surface area of the W layer 230 is increased. Since the surface area of the W layer 230 is increased in the present invention, the contact resistance of the contact plug 232 can be further decreased.

Thereafter, while not shown in the drawings, by sequentially conducting a series of well-known subsequent processes, the manufacture of a semiconductor device according to one embodiment of the present invention is completed.

As is apparent from the above description, in the present invention, due to the fact that secondary annealing is conducted after a barrier layer is formed on the surface of a contact hole in which a CoSi layer and an amorphous Si-rich layer are formed, the amorphous Si-rich layer can be removed through reaction of the CoSi layer and the amorphous Si-rich layer. Accordingly, in the present invention, it is possible to prevent contact resistance from increasing due to the presence of the amorphous Si-rich layer.

Also, in the present invention, a CoSi₂ layer having a uniform thickness can be formed on the bottom of the contact hole through the secondary annealing by adjusting the thickness of the barrier layer, and through this, leakage current can be decreased.

Meanwhile, the above-described process for forming a contact plug according to the embodiment of the present invention can be applied not only to a bit line contact plug to be formed on the junction region of a semiconductor substrate, but also to other contact plugs to be formed by placing an ohmic contact layer through a silicide process.

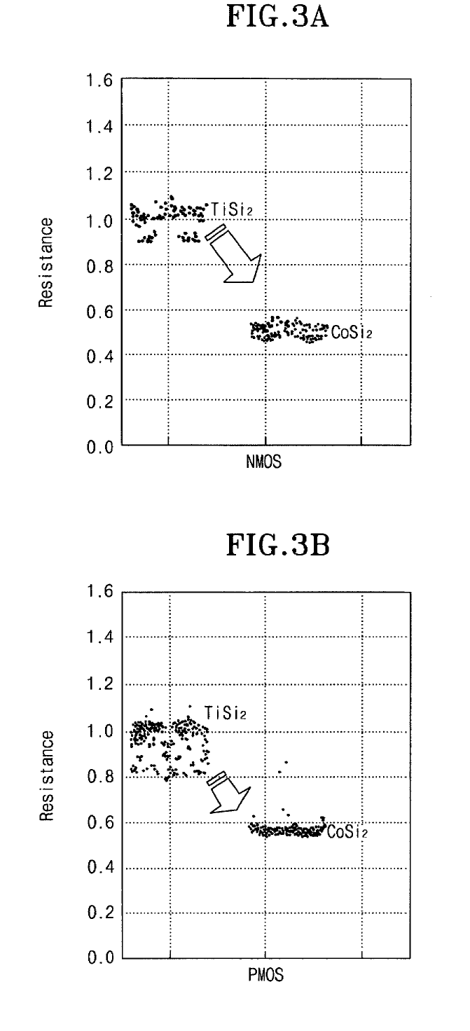

FIGS. 3A and 3B are graphs showing resistance of an NMOS device and a PMOS device when a contact plug is formed in accordance with the embodiment of the present invention.

Referring to FIGS. 3A and 3B, it is shown that, when the amorphous Si-rich layer is removed while forming the CoSi₂ layer on the bottom of the contact hole according to the embodiment of the present invention as described above, contact resistance is decreased when compared to the case of forming a TiSi₂ layer on the bottom of the contact hole according to the conventional art.

For example, in the present invention, the contact resistance of an NMOS device and a PMOS device can be decreased about 48% and 40%, respectively, when compared to the conventional art.

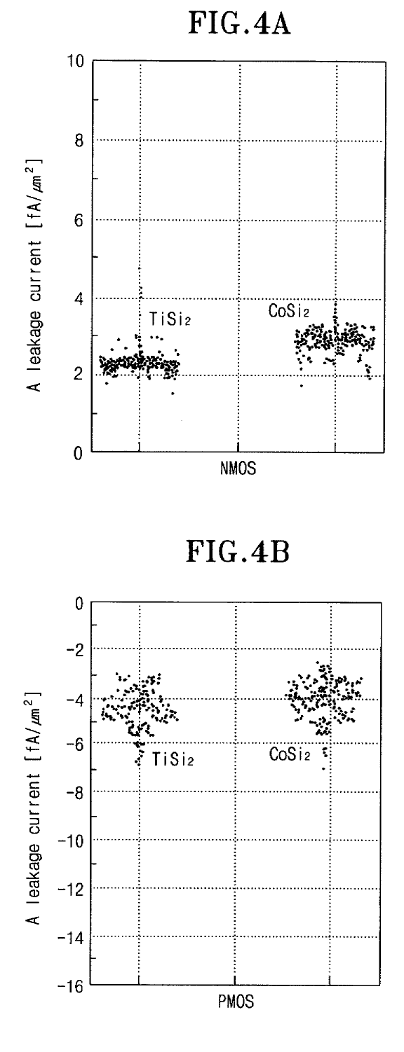

FIGS. 4A and 4B are graphs showing leakage current of an NMOS device and a PMOS device when a contact plug is formed in accordance with the embodiment of the present invention.

Referring to FIGS. 4A and 4B, it is shown that, when the amorphous Si-rich layer is removed while forming the CoSi₂ layer on the bottom of the contact hole according to the embodiment of the present invention, leakage current is produced to a level similar to the conventional art in which a TiSi₂ layer is formed on the bottom of the contact hole.

Therefore, in the present invention, by removing the amorphous Si-rich layer formed on the CoSi₂ layer, the contact resistance of both of the NMOS device and the PMOS device can be decreased while preventing the leakage current from increasing.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for manufacturing a semiconductor device, comprising the steps of:
forming an insulation layer having a contact hole, on a semiconductor substrate;
forming a Co layer on the insulation layer and a surface of the contact hole;
conducting a primary annealing such that the Co layer reacts with a corresponding portion of the semiconductor substrate so as to form a CoSi layer at an interface of the Co layer and the corresponding portion of the semiconductor substrate;
cleaning the resultant semiconductor substrate so as to remove a portion of the Co layer not having reacted in the primary annealing;
forming a barrier layer on the insulation layer, the CoSi layer, and the surface of the contact hole; and
converting the CoSi layer into a CoSi₂ layer through a secondary annealing.

2. The method according to claim 1, wherein, the method further comprises the step of:
after forming the insulation layer and before forming the Co layer, removing a native oxide layer produced on a surface of the insulation layer having the contact hole.

3. The method according to claim 1, wherein, the method further comprises the step of:
after forming the Co layer and before conducting the primary annealing, forming a capping layer on the Co layer.

4. The method according to claim 3, wherein the capping layer comprises at least one of a Ti layer and a TiN layer.

5. The method according to claim 3, wherein forming the Co layer and forming the capping layer are implemented in situ.

6. The method according to claim 1, wherein the primary annealing is conducted through rapid thermal annealing (RTA).

7. The method according to claim 1, wherein the primary annealing is conducted at a temperature in the range of 400˜550° C.

8. The method according to claim 1, wherein cleaning is conducted using an sulfuric acid peroxide mixture (SPM) solution.

9. The method according to claim 1, wherein the barrier layer comprises a stacked structure of a Ti layer and a TiN layer.

10. The method according to claim 1, wherein the secondary annealing is conducted through RTA.

11. The method according to claim 1, wherein the secondary annealing is conducted at a temperature in the range of 700˜800° C.

12. The method according to claim 1, wherein, the method further comprises the steps of:
after conducting the secondary annealing, forming a glue layer on the barrier layer; and
forming a conductive layer on the glue layer to fill the contact hole.

13. The method according to claim 12, wherein the glue layer comprises a TiN layer.

14. The method according to claim 12, wherein the conductive layer comprises a W layer.

15. A method for manufacturing a semiconductor device, comprising the steps of:
forming a gate on a semiconductor substrate;
forming a junction region in a surface of the semiconductor substrate at both sides of the gate;
forming an insulation layer on the semiconductor substrate formed with the junction region, wherein the insulation layer has a hole defined therein to expose the junction region;
forming a Co layer on the insulation layer and a surface of the contact hole;
conducting a primary annealing such that the Co layer reacts with a corresponding portion of the semiconductor substrate so as to form a CoSi layer at an interface of the Co layer and the corresponding portion of the semiconductor substrate;
cleaning the resultant semiconductor substrate so as to remove a portion of the Co layer not having reacted in the primary annealing;
forming a barrier layer on the insulation layer, the CoSi layer, and the surface of the contact hole; and
converting the CoSi layer into a CoSi₂ layer through a secondary annealing.

16. The method according to claim 15, wherein, the method further comprises the step of:
after forming the insulation layer and before forming the Co layer, removing a native oxide layer produced on a surface of the junction region which constitutes a bottom of the contact hole.

17. The method according to claim 15, wherein, the method further comprises the step of:
after forming the Co layer and before conducting the primary annealing, forming a capping layer on the Co layer.

18. The method according to claim 17, wherein the capping layer comprises at least one of a Ti layer and a TiN layer.

19. The method according to claim 17, wherein forming the Co layer and forming the capping layer are implemented in situ.

20. The method according to claim 15, wherein the primary annealing is conducted through RTA.

21. The method according to claim 15, wherein the primary annealing is conducted at a temperature in the range of 400˜550° C.

22. The method according to claim 15, wherein cleaning is conducted using an SPM solution.

23. The method according to claim 15, wherein the barrier layer comprises a stacked structure of a Ti layer and a TiN layer.

24. The method according to claim 15, wherein the secondary annealing is conducted through RTA.

25. The method according to claim 15, wherein the secondary annealing is conducted at a temperature in the range of 700˜800° C.

26. The method according to claim 15, wherein, the method further comprises the steps of:
after conducting the secondary annealing, forming a glue layer on the barrier layer; and
forming a conductive layer on the glue layer to fill the contact hole.

27. The method according to claim 26, wherein the glue layer comprises a TiN layer.

28. The method according to claim 26, wherein the conductive layer comprises a W layer.
